(19) United States
(12) Patent Application Publication
(10) Pub. No.: US 2020/0161080 A1
(43) Pub. Date: May 21, 2020

(54) ELECTRON MICROSCOPE SPECIMEN MOUNT

(71) Applicant: EMCRAFTS CO., LTD., Gwangju-si (KR)

(72) Inventor: Jung Bum CHUN, Gwangju-si (KR)

(21) Appl. No.: 16/287,770

(22) Filed: Feb. 27, 2019

(30) Foreign Application Priority Data
Nov. 16, 2018 (KR) 10-2018-0141573

(51) Int. Cl. H01J 37/20; H01J 37/26; H01J 37/32

(52) U.S. Cl. CPC H01J 37/20; H01J 37/32724; H01J 37/261

(57) ABSTRACT

Provided is an electron microscope specimen mount. The electron microscope specimen mount can include a stage. The electron microscope specimen mount can also include a cooling specimen holder provided on a top surface of the stage and configured to receive power and cool down a measurement target specimen to a certain temperature. The electron microscope specimen mount can further include a room-temperature specimen holder separated from the cooling specimen holder. The cooling specimen holder and the room-temperature specimen holder can be selectively used.

### CROSS-REFERENCE TO RELATED APPLICATION

This application claims the benefit of Korean Patent Application No. 10-2018-0141573, filed on Nov. 16, 2018, in the Korean Intellectual Property Office, the disclosure of which is incorporated herein in its entirety by reference.

### BACKGROUND

### 1. Field

One or more embodiments relate to an electron microscope specimen mount, and more particularly, to an electron microscope specimen mount allowing both a cooling specimen holder and a room-temperature specimen holder to be provided together on a single stage.

### 2. Description of the Related Technology

In general, scanning electron microscopes (hereinafter, referred to as “electron microscopes”) obtain information about a specimen that is a target of measurement through a procedure in which the specimen is positioned in a vacuum chamber and an electron beam generated by an electron gun in a tube is scanned across the specimen. In other words, electron microscopes may obtain information about a specimen through a series of a process of detecting an electronic signal generated when an electron beam emitted from a filament collides with the surface of the specimen and a process of displaying the detected electronic signal as an image or recording the detected electronic signal in a recording medium.

A vacuum chamber is essential for the use of such electron microscopes because a filament generating an electron beam may react with a gas and be consumed when the filament is heated. In addition, the vacuum chamber is essential to prevent an electron beam from colliding with other gas molecules in the path of the electron beam. When an electron beam collides with other gases on its path, it is hard to anticipate fine optical characteristics. Furthermore, since an Everhart-Thornley (E-T) detector used as a secondary electron detector uses a high voltage of about 10 kV to attract secondary electrons, gas molecules lose electrons to become plasma and generate light, thereby acting as noise to the secondary electron detector.

Recent techniques use a backscattered electron detector instead of a secondary electron detector, thereby reducing a vacuum level of a vacuum chamber to 10⁻¹ Torr through 10⁻² Torr. However, when a liquid specimen or a specimen having a high moisture content is observed, it is difficult to satisfy a required vacuum level because of rapid evaporation. In addition, a specimen is easy to lose its original shape due to evaporation of moisture. Therefore, a drying method such as freeze-drying or critical point drying is used to observe a liquid specimen. Alternatively, a method of freezing moisture by cooling down a specimen itself to about −20° C. is used. When a specimen is frozen, moisture evaporation is slowed down so that a desired vacuum state may be obtained and there is not much change in the shape of the specimen, and therefore, freezing methods are more frequently used than drying methods requiring complex preprocessing. Korea Application Publication 10-2012-0107716 (published on Oct. 4, 2012) discloses such a method of cooling a specimen.

In detail, a Peltier element is usually used in specimen cooling methods according to the related art. When current flows across a Peltier element, a difference in temperature occurs between two sides. At this time, when heat generated from the side having a higher temperature is discharged outside through a medium such as water, the side having a lower temperature may be maintained at a low temperature of about −25° C.

A cooling specimen holder using such a cooling method is mounted on a usual stage, replacing a room-temperature specimen holder. However, whenever the room-temperature specimen holder needs to be used, the cooling specimen holder needs to be removed from the stage, causing inconvenience.

### SUMMARY

One or more embodiments include an electron microscope specimen mount allowing both a cooling specimen holder and a room-temperature specimen holder to be provided together on a single stage and to be selectively used.

Additional aspects will be set forth in part in the description which follows and, in part, will be apparent from the description, or may be learned by practice of the presented embodiments.

According to one or more embodiments, an electron microscope specimen mount includes a stage, a cooling specimen holder provided on a top surface of the stage and configured to receive power and cool down a measurement target specimen to a certain temperature, and a room-temperature specimen holder separated from the cooling specimen holder on the top surface of the stage.

The cooling specimen holder may include a Peltier element coupled to the top surface of the stage and including an electrode and a cooling plate stacked on a top of the Peltier element and having the measurement target specimen on a top surface thereof. The cooling plate contacting a top surface of the Peltier element may become a low-temperature part and the stage contacting a bottom surface of the Peltier element may become a high-temperature part.

The room-temperature specimen holder may include a body on which the measurement target specimen is positioned and a coupling protrusion protruding below the body and being removably inserted into and coupled to a coupling recess portion provided on the top surface of the stage.

A position of the room-temperature specimen holder may be fixed via a fixing member fastened to a fastening hole at a side of the coupling recess portion after the coupling protrusion is coupled to the coupling recess portion.

A plurality of room-temperature specimen holders may be arranged separated from each other around the cooling specimen holder.

The stage may include a cooling module configured to cool down the stage heated in contact with the bottom surface of the Peltier element. The cooling module may include a coolant inlet provided at a side of the stage, a coolant circulation portion provided inside the stage and configured to allow a coolant supplied through the coolant inlet to circulate, and a coolant outlet configured to allow the coolant circulated through the coolant circulation portion to be discharged.

According to the electron microscope specimen mount, a cooling specimen holder and a room-temperature specimen holder are provided on a single stage, so that one of the cooling specimen holder and the room-temperature specimen holder may be easily and selectively used according to a type of measurement target specimen. In other words, the room-temperature specimen holder may be used without removing the cooling specimen holder even when the cooling specimen holder is not used, so that a work efficiency may be increased.

### BRIEF DESCRIPTION OF THE DRAWINGS

These and/or other aspects will become apparent and more readily appreciated from the following description of the embodiments, taken in conjunction with the accompanying drawings.

FIG. 1 is a perspective view of an electron microscope specimen mount according to an embodiment.

FIG. 2 is an exploded perspective view of an electron microscope specimen mount according to an embodiment.

FIG. 3 is a perspective view of a room-temperature specimen holder, according to an embodiment.

FIGS. 4A and 4B are lateral cross-sectional views of the assembly structure of a room-temperature specimen holder, according to an embodiment.

FIG. 5 is a plan view of an electron microscope specimen mount according to an embodiment.

FIG. 6 is a side view of the configuration of a cooling module according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

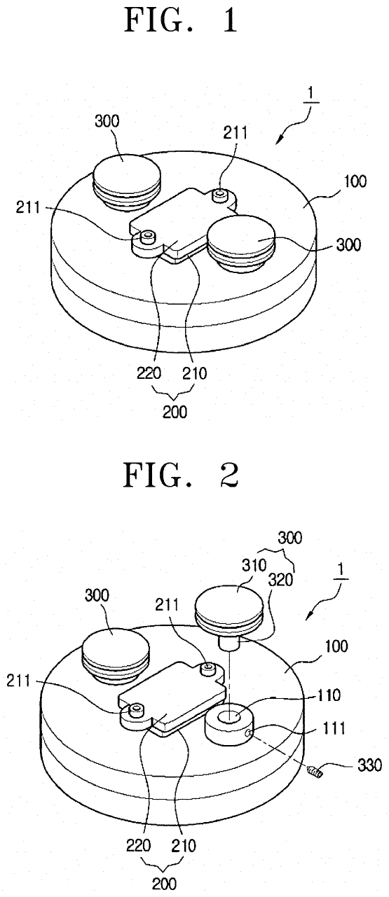

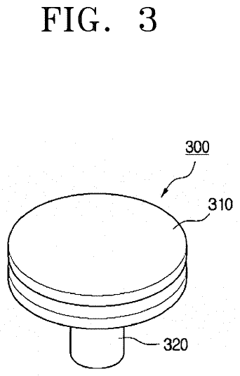

FIG. 1 is a perspective view of an electron microscope specimen mount according to an embodiment. FIG. 2 is an exploded perspective view of an electron microscope specimen mount according to an embodiment. FIG. 3 is a perspective view of a room-temperature specimen holder, according to an embodiment.

Referring to FIG. 1, an electron microscope specimen mount 1 includes a stage 100, a cooling specimen holder 200, and a room-temperature specimen holder 300. In detail, the stage 100 forms a main body of the electron microscope specimen mount 1. The stage 100 is removably installed in a vacuum chamber (not shown) included in an electron microscope.

In this case, the vacuum chamber has a receiving space having a door (not shown) on at least one side thereof such that the stage 100 having a measurement target specimen is positioned inside the vacuum chamber through the door. Since the vacuum chamber has a usual structure applied to electron microscopes according to the related art, detailed descriptions of the vacuum chamber will be omitted.

The cooling specimen holder 200 receives power and cools down a measurement target specimen to a certain temperature. The cooling specimen holder 200 may be provided in a central portion of a top surface of the stage 100.

Referring to FIG. 2, the cooling specimen holder 200 may include a Peltier element 210 and a cooling plate 220. The Peltier element 210 includes an electrode 211 at a side thereof to receive power. The cooling plate 220 is stacked on a top of the Peltier element 210. A measurement target specimen is positioned on a top of the cooling plate 220. In this case, the cooling plate 220 contacting a top surface of the Peltier element 210 becomes a low-temperature part and the stage 100 contacting a bottom surface of the Peltier element 210 becomes a high-temperature part.

A plurality of room-temperature specimen holders 300 are arranged separated from each other around the cooling specimen holder 200. Each of the room-temperature specimen holders 300 is used to obtain information about an ordinary measurement target specimen that does not need to be cooled. In other words, the electron microscope specimen mount 1 allows one of the cooling specimen holder 200 and the room-temperature specimen holders 300 to be selectively used.

Referring to FIG. 3, the room-temperature specimen holder 300 may include a body 310, on which a measurement target specimen is positioned, and a coupling protrusion 320 protruding below the body 310. The coupling protrusion 320 may be removably inserted into and coupled to a coupling recess portion 110 on the top surface of the stage 100.

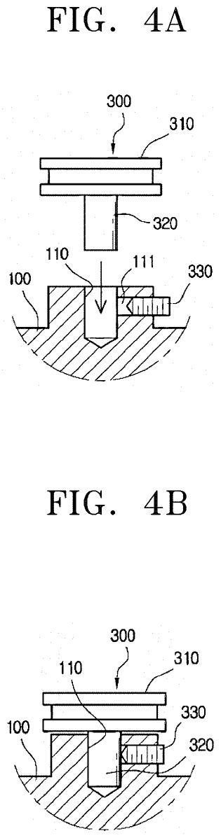

FIGS. 4A and 4B are lateral cross-sectional views of the assembly structure of the room-temperature specimen holder 300, according to an embodiment. After the coupling protrusion 320 is inserted into and coupled to the coupling recess portion 110 of the stage 100, the position of the room-temperature specimen holder 300 may be fixed via a fixing member 330 fastened to a fastening hole 111 at a side of the coupling recess portion 110. The fixing member 330 may include a bolt or a setscrew. The fixing member 330 presses an outer circumference of the coupling protrusion 320 inserted into the coupling recess portion 110, thereby firmly fixing the room-temperature specimen holder 300.

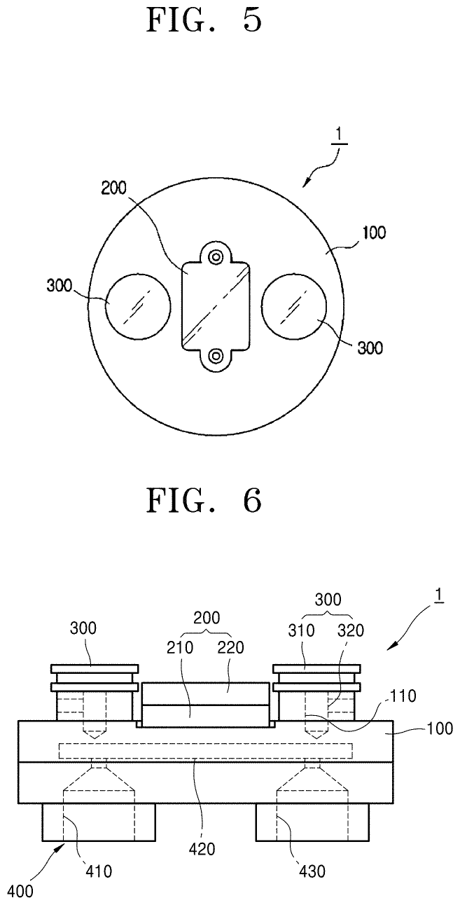

FIG. 5 is a plan view of the electron microscope specimen mount 1 according to an embodiment. In the embodiments, an example in which two room-temperature specimen holders 300 are arranged separated from each other around the cooling specimen holder 200 is illustrated and described. However, the present disclosure is not limited to these embodiments, and more than two room-temperature specimen holders 300 may be provided.

FIG. 6 is a side view of the configuration of a cooling module according to an embodiment. Referring to FIG. 6, the stage 100 may include a cooling module 400 cooling down the stage 100 heated in contact with the bottom surface of the Peltier element 210 of the cooling specimen holder 200.

The Peltier element 210 uses a phenomenon in which a difference in temperature is maintained between opposite sides of a stack of a plurality of conductive layers when current flows across the stack. When a hot side which is opposite a cold side requiring low-temperature cooling is forcedly cooled down, heat of the cold side is transferred to the hot side in the Peltier element 210. In other words, one side gets cooler while the other side gets hotter due to the Seebeck effect. Accordingly, a side getting hot needs to be cooled properly to increase efficiency. When the side is overheated, efficiency decreases, and eventually, an element is broken or the cold side may be switched with the hot side due to thermal reversion.

For the reasons described above, the cooling module 400 is used to cool down the bottom surface of the Peltier element 210, thereby increasing the efficiency of the cooling specimen holder 200. In detail, the cooling module 400 may include a coolant inlet 410 provided at a side of the stage 100, a coolant circulation portion 420 which is provided inside the stage 100 and through which a coolant supplied through the coolant inlet 410 is circulated, and a coolant outlet 430 through which the coolant circulated through the coolant circulation portion 420 is discharged.

As described above, the electron microscope specimen mount 1 has the cooling specimen holder 200 and the room-temperature specimen holder 300 together on a single stage, i.e., the stage 100, so that one of the cooling specimen holder 200 and the room-temperature specimen holder 300 may be easily and selectively used according to a type of measurement target specimen. In other words, the room-temperature specimen holder 300 may be used without removing the cooling specimen holder 200 even when the cooling specimen holder 200 is not used, so that a work efficiency may be increased.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the disclosure as defined by the following claims.

What is claimed is:

1. An electron microscope specimen mount comprising:
a stage;
a cooling specimen holder provided on a top surface of the stage and configured to receive power and cool down a measurement target specimen to a certain temperature; and
a room-temperature specimen holder separated from the cooling specimen holder.

2. The electron microscope specimen mount of claim 1, wherein the cooling specimen holder comprises:
a Peltier element coupled to the top surface of the stage and including an electrode; and
a cooling plate stacked on a top of the Peltier element and having the measurement target specimen on a top surface thereof,
wherein the cooling plate contacting a top surface of the Peltier element is configured to function as a low-temperature part and the stage contacting a bottom surface of the Peltier element is configured to function as a high-temperature part.

3. The electron microscope specimen mount of claim 1, wherein the room-temperature specimen holder comprises:
a body on which the measurement target specimen is positioned; and
a coupling protrusion protruding below the body and being removably inserted into and coupled to a coupling recess portion provided on the top surface of the stage.

4. The electron microscope specimen mount of claim 3, wherein a position of the room-temperature specimen holder is fixed via a fixing member fastened to a fastening hole at a side of the coupling recess portion after the coupling protrusion is coupled to the coupling recess portion.

5. The electron microscope specimen mount of claim 1, wherein a plurality of room-temperature specimen holders are arranged separated from each other around the cooling specimen holder.

6. The electron microscope specimen mount of claim 2, wherein the stage comprises a cooling module configured to cool down the stage heated in contact with the bottom surface of the Peltier element,
wherein the cooling module comprises:
a coolant inlet provided at a side of the stage;
a coolant circulation portion provided inside the stage and configured to allow a coolant supplied through the coolant inlet to circulate; and
a coolant outlet configured to allow the coolant circulated through the coolant circulation portion to be discharged.
